(19) United States
(12) Patent Application Publication
(10) Pub. No.: US 2006/0252160 A1
(43) Pub. Date: Nov. 9, 2006

(54) Electron beam exposure device and exposure method

(75) Inventors: Tadahiro Ohmi, Miyagi (JP); Shigetoshi Sugawa, Miyagi (JP); Kimio Yanagida, Fukushima (JP); Kiwamu Takehisa, Miyagi (JP)

Correspondence Address: FOLEY AND LARDNER LLP;SUITE 500, 3000 K STREET NW, WASHINGTON, DC, 20007, US

(73) Assignee: Tadahiro OHMI

(21) Appl. No.: 10/567,828

(22) PCT Filed: Aug. 9, 2004
(86) PCT No.: PCT/JP04/11720

§ 371 Date: Apr. 28, 2006

(30) Foreign Application Priority Data
Aug. 12, 2003 (JP) 2003-292528

(51) Int. Cl. C23C 16/00; H01L 21/00

(52) U.S. Cl. 438/1; 118/723 CB

(57) ABSTRACT

A 1:1 mask and a wafer are arranged so as to be vertical. Thus, a pattern portion of the 1:1 mask does not warp at all and, therefore, even when the mask has no beam, it is not necessary to strongly stretch a pattern portion thereof. Further, a gap between the mask and the wafer can be further reduced. Since it is not necessary to strongly stretch the pattern portion of the stencil mask, a very thin membrane can be bonded to the pattern portion. Thus, even when the acceleration voltage of an electron beam is as low as several kV, it is possible to use a mask called a membrane mask and carry out pattern formation by one-time exposure even in the case of a doughnut-shaped pattern.

### TECHNICAL FIELD

This invention relates to an exposure apparatus for use in an exposure process that may be one of semiconductor manufacturing processes and, more specifically, relates to a structure of an electron beam exposure apparatus using a 1:1 mask (namely, proximity mask) and an exposure method thereof.

### BACKGROUND ART

Generally, in exposure apparatuses, there are a case of using light, particularly ultraviolet light, as an exposure light source and a case of using an electron beam, and the latter is widely called an electron beam exposure apparatus. The electron beam exposure apparatuses are roughly classified into two systems one of which is an electron beam direct writing apparatus adapted to directly irradiate an electron beam onto a wafer. The other is the system that uses a mask with a structure having an open-through pull-out portion shaped into a pattern to be exposed (generally called a stencil mask wherein, for example, on exposing a letter “A”, if an island-like portion is included as shown in FIG. 4, exposure is required twice by the use of two masks) and irradiates an electron beam onto the mask so that the electron beam having passed through the pattern portion in the mask is irradiated onto a wafer, thereby carrying out pattern writing (exposure in the shape of the pattern). Further, the electron beam exposure apparatuses using the latter mask can also be roughly classified into two. One is a reduction-projection exposure apparatus which uses a mask having a pattern that has a size of about four times as compared with a pattern to be actually exposed (this is called an electron beam reduction-projection exposure apparatus). As a structural example, like in an electron beam reduction-projection exposure apparatus 200 shown in FIG. 2, an electron beam 22 produced by an electron gun 21 passes through a deflector 23 so as to be irradiated onto a stencil mask 24. The electron beam having proceeded through an open-through portion in the shape of a pattern in the stencil mask 24 passes through an electron lens 25 so as to be irradiated onto a wafer 26. That is, the pattern of the stencil mask 24 is reduction-projected onto the wafer 26.

Such an electron beam reduction-projection exposure apparatus is called an EPL (Electron Projection Lithography) and shown, for example, in the February 2002 issue of Electronic Journal, pp. 62-65.

The other one of the electron beam exposure apparatuses is a proximity exposure apparatus using a stencil mask having a pattern equal in size to a pattern to be actually exposed (this is called an electron beam proximity exposure apparatus). As a structural example, like in an electron beam proximity exposure apparatus 300 shown in FIG. 3, an electron beam 32 irradiated from an electron gun 31 passes through an electron lens 33, an aperture 34, a main deflector 35, and a strain correction deflector 36 so as to be irradiated onto a 1:1 mask 37 disposed right above a wafer 38. Since the 1:1 mask 37 is a stencil mask, the electron beam having proceeded through an open-through portion thereof is irradiated onto the wafer 38. Thus, the wafer 38 is pattern-exposed.

Such an electron beam proximity exposure apparatus is widely called an LEEPL (Low Energy E-Beam Proximity Lithography) and shown, for example, in the Dec. 17, 2001 issue of Nikkei Electronics, pp. 33-34. According to this, the stencil mask used in the LEEPL is called a quadrant complementary mask having a pattern portion where beams (grid) are arranged lengthwise and crosswise at a several mm square pitch. As a result, since beam portions cannot be exposed, it is necessary to carry out overlay or stitch exposure of four patterns for forming a single circuit pattern on a wafer.

### DISCLOSURE OF THE INVENTION

On the other hand, since the quadrant complementary mask is low in throughput, a stencil mask having no beam (sometimes called a support-free LEEPL mask) is proposed as shown in FIG. 5. However, in order to prevent warping of a wide and thin pattern portion, the pattern portion should be strongly stretched and fixed on a mask substrate. As a result, a time is prolonged that is required for damping of vibration generated at the pattern portion at the time of setting the mask or the like so that a wasteful stopping time occurs up to the start of exposure, and therefore, the throughput cannot be increased.

Further, even if the pattern portion is strongly stretched close to the destruction limit, the warping cannot be reduced to zero theoretically and, therefore, it is not possible to narrow a gap between the mask and a wafer to less than a certain value. As a result, exposure blur, which is caused by spreading of an electron beam having proceeded through the mask until it reaches the wafer, cannot be reduced to less than a certain level.

An object of this invention is to provide an electron beam proximity exposure apparatus that can fix a 1:1 mask used in the apparatus, particularly the mask having no beam, without strongly stretching a pattern portion thereof.

For accomplishing the foregoing object, in an electron beam proximity exposure apparatus of this invention, a 1:1 mask and a wafer are arranged so as to be substantially vertical. In other words, according to this invention, there is obtained an electron beam proximity exposure apparatus wherein a 1:1 mask and a wafer are arranged so as to be parallel to the gravity direction. According to this structure, a pattern portion of the 1:1 mask does not warp at all and, therefore, it is not necessary to strongly stretch the pattern portion of, particularly, even the mask having no beam. Further, a gap between the mask and the wafer can be further reduced.

### BRIEF DESCRIPTION OF THE DRAWINGS

FIG. 1 is a schematic structural diagram showing a structure of an electron beam proximity exposure apparatus according to an embodiment of this invention.

FIG. 2 is a diagram showing a structure of an electron beam reduction-projection exposure apparatus.

FIG. 3 is a diagram showing a structure of a conventional electron beam proximity exposure apparatus.

FIG. 4 is a perspective view showing a pattern portion of a general stencil mask.

FIG. 5 is a sectional view showing a structure of a general stencil mask.

FIG. 6 is a sectional view showing a structure of a stencil mask of this invention.

### BEST MODE FOR CARRYING OUT THE INVENTION

Hereinbelow, an embodiment of this invention will be described with reference to the drawings.

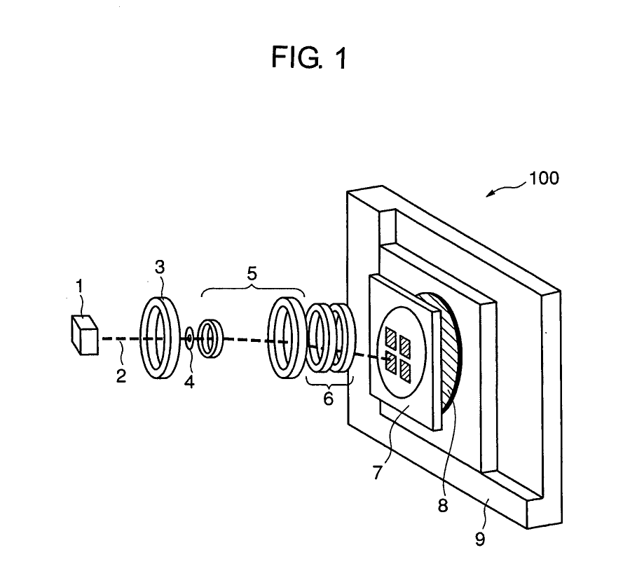

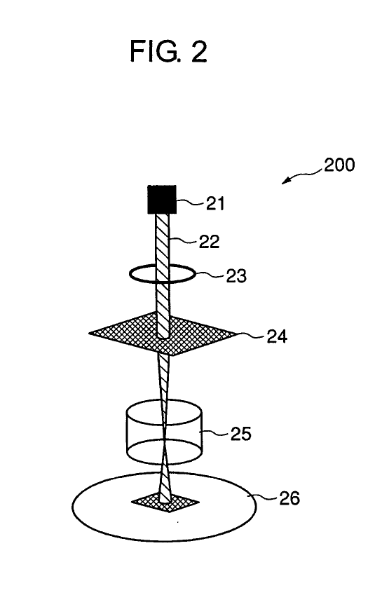

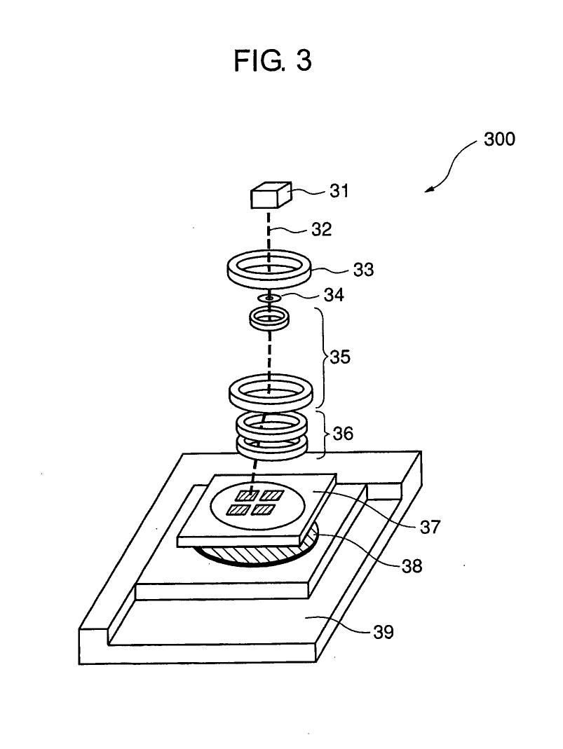

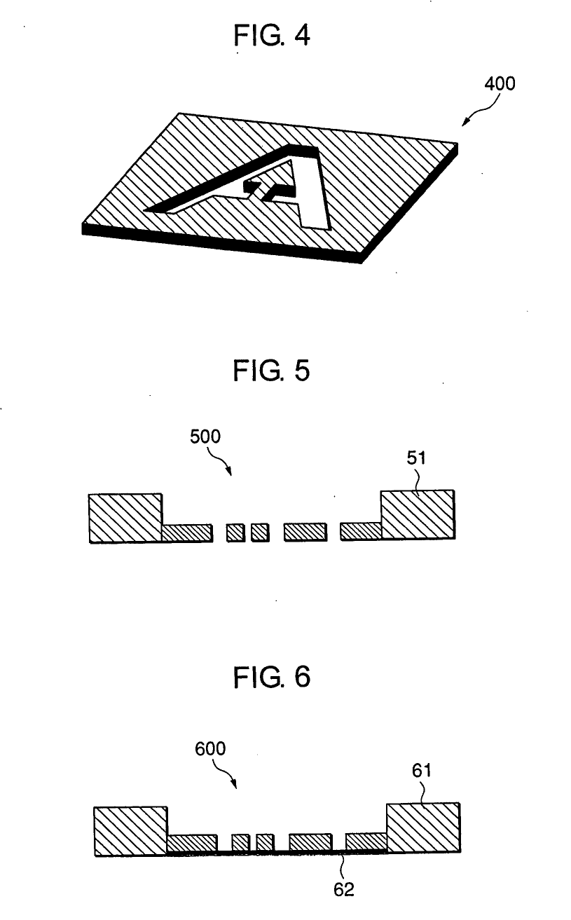

FIG. 1 is a diagram showing a structure of an electron beam proximity exposure apparatus 100 according to the embodiment of this invention, wherein the structure is similar to the conventional electron beam proximity exposure apparatus 300 shown in FIG. 3 but is laid sideways. An electron beam 2 irradiated from an electron gun 1 proceeds substantially horizontally and passes through an electron lens 3, an aperture 4, a main deflector 5, and a strain correction deflector 6 so as to be irradiated onto a 1:1 mask 7 disposed immediately before a wafer 8. Since the 1:1 mask 7 is a stencil mask, the electron beam having proceeded through an open-through portion thereof is irradiated onto the wafer 8. Thus, the wafer 8 is pattern-exposed. The wafer 8 is fixed to a vertical stage 9 and, therefore, the 1:1 mask 7 and the wafer 8 are fixed vertically. The wafer 8 can move left and right and up and down in the vertical stage 9. An interval between the wafer 8 and the mask 7 may be set to a known distance.

In this embodiment, since the 1:1 mask 7 is vertically arranged in the electron beam proximity exposure apparatus 100, its pattern portion is not subjected to warping due to gravity. As a result, the gap between the 1:1 mask 7 and the wafer 8 can be narrowed to no more than 10 microns which is smaller than conventional by several times. According to this structure, blur, which is caused by spreading, in the gap, of the electron beam irradiated onto the wafer 8, is also suppressed to a factor of several.

Further, as a result of the 1:1 mask 7 not being subjected to warping due to gravity, it is not necessary to strongly stretch its pattern portion. Consequently, it becomes possible to use, as the 1:1 mask 7, a stencil mask 600 having a membrane 62 as shown in FIG. 6. That is, this is because even the very thin membrane 62 can be used without breakage. According to this, even an island-like pattern, which cannot be exposed by one-time exposure with a normal stencil mask shown in FIG. 5, can be exposed by one-time exposure. Since a material such as diamond-like carbon, which has high strength and can be made thin, can be used as a material of the membrane 62, it is possible to form a stencil mask that is very thin and yet has high strength.

In the embodiment, the mask 7 and the wafer 8 are held so as to be vertical. However, even if they are inclined from vertical by about ±10° (this is also included in “substantially vertical” in this invention), it is possible to largely prevent warping of a 1:1 mask. Likewise, the electron beam 2 may also be caused to proceed so as to be inclined from horizontal by about ±10°.

As described above, in this invention, it is not necessary to strongly stretch the pattern portion of the 1:1 mask having no beam. As a result, the pattern portion is not subjected to vibration and, therefore, the exposure can be started immediately after the mask has been set.

Further, since it is not necessary to strongly stretch the pattern portion of the stencil mask, the very thin membrane can be bonded to the pattern portion. Thus, even when, for example, the acceleration voltage of an electron beam is as low as several kV like in the LEEPL, it is possible to use a mask called a membrane mask and carry out pattern formation by one-time exposure even in the case of a doughnut-shaped pattern.

Moreover, since the pattern portion does not warp at all, the gap between the mask and the wafer can be further reduced so that it is possible to suppress blur of the electron beam after having passed through the mask.

1. An electron beam exposure apparatus comprising electron beam irradiation means, means for holding an irradiation-target substrate, and means for holding a 1:1 mask to be placed near said irradiation-target substrate between said electron beam irradiation means and said irradiation-target substrate, said electron beam exposure apparatus characterized in that said means for holding said irradiation-target substrate and said means for holding said 1:1 mask hold said irradiation-target substrate and said 1:1 mask substantially vertical, respectively.

2. An electron beam exposure apparatus according to claim 1, characterized in that said means for holding said irradiation-target substrate and said means for holding said 1:1 mask keep said irradiation-target substrate and said 1:1 mask substantially parallel to each other.

3. An electron beam exposure method for irradiating an electron beam from electron beam irradiation means onto an irradiation-target substrate through a 1:1 mask in a pattern determined by said 1:1 mask, said electron beam exposure method characterized by arranging said irradiation-target substrate and said 1:1 mask substantially vertical, respectively.

4. An electron beam exposure method according to claim 3, characterized by using, as said 1:1 mask, a mask having a thin membrane in which at least part of a beam of a pattern portion of the mask is omitted.

5. An electron beam exposure method according to claim 4, characterized by using the 1:1 mask comprising the thin membrane having no beam at the pattern portion.

6. A semiconductor device manufacturing method characterized in that said irradiation-target substrate is a semiconductor wafer and by comprising at least a process of exposing said semiconductor wafer by the use of the electron beam exposure apparatus according to claim 1 or 2.

7. A semiconductor device manufacturing method characterized in that said irradiation-target substrate is a semiconductor wafer and by comprising at least a process of exposing said semiconductor wafer by the electron beam exposure method according to any one of claims 3 to 5.

8. An electron beam exposure apparatus comprising a 1:1 mask and an irradiation-target substrate arranged so as to face said 1:1 mask, said electron beam exposure apparatus characterized in that said 1:1 mask and said irradiation-target substrate are arranged so as to be parallel to a gravity direction.
